(19) United States
(12) Patent Application Publication
(10) Pub. No.: US 2024/0348483 A1
(43) Pub. Date: Oct. 17, 2024

(54) TRANSMITTING DEVICE, RECEIVING DEVICE, COMMUNICATION APPARATUS, AND METHODS OF WIRELESS COMMUNICATION

(71) Applicant: HUAWEI TECHNOLOGIES CO., LTD., Shenzhen (CN)

(72) Inventors: Kamel TOURKI, Munich (DE); Merouane DEBBAH, Munich (DE); Rostom ZAKARIA, Munich (DE)

(21) Appl. No.: 18/750,602

(22) Filed: Jun. 21, 2024

Related U.S. Application Data
(63) Continuation of application No. PCT/EP2021/087454, filed on Dec. 23, 2021.

(51) Int. Cl. H04L 27/26; H03M 13/00; H04B 7/0456

(52) U.S. Cl. CPC H04L 27/2639; H03M 13/6312; H04B 7/0456

(57) ABSTRACT

The present disclosure relates to transmitting devices and receiving devices. An example transmitting device includes a data symbol generation circuit configured to generate a vector of data symbols, a precoding circuit configured to precode the vector of data symbols, and a modulation circuit configured to modulate the precoded vector of data symbols. The modulation circuit modulates the precoded vector of data symbols based on a predetermined modulation matrix to generate a modulated precoded vector of data symbols. The predetermined modulation matrix includes a plurality of discrete prolate spheroidal sequences. The modulated precoded vector of data symbols is transmitted in a Slepian-based waveform to a receiving device.

### CROSS-REFERENCE TO RELATED APPLICATIONS

This application is a continuation of International Application No. PCT/EP2021/087454, filed on Dec. 23, 2021, the disclosure of which is hereby incorporated by reference in its entirety.

### TECHNICAL FIELD

The present disclosure relates generally to the field of wireless communication and, more specifically, to a transmitting device, a receiving device, a communication apparatus, and methods of wireless communication.

### BACKGROUND

In order to satisfy the diversified requirements of end-users, wireless communication networks, such as fifth-generation (5G) networks and upcoming beyond 5G networks, may require access to different frequency bands. A typical multi-layer spectrum layout has been defined accordingly, where a super data layer relies on a spectrum of above 6 GHz (e.g., 24.25-29.5 GHz and 37-43.5 GHZ) to address specific use cases that require extremely high data rates, such as enhanced mobile broadband (eMBB). The coverage and capacity layers of the typical multi-layer spectrum rely on a spectrum in the 2 to 6 GHz range (e.g., C band) to deliver a suitable trade-off between capacity and coverage. The typical applications include ultra-reliable low-latency communications (URLLC), massive machine-type communications (mMTC), and eMBB. The coverage layer exploits the spectrum below 2 GHz (e.g., 1.8 GHz) to provide wide-area coverage and deep indoor coverage. The typical applications include, for example, the URLLC, the mMTC, and the eMBB.

The coverage and capacity layers are of great significance, since most of the 5G use cases rely on these layers. It has already been stated in third-generation partnership project (3GPP) specifications (e.g., in Release 16 of 5G networks) that a contiguous band of 100 MHz has been assigned to the coverage and capacity layers. However, it is estimated that a single-band solution (or assigning the contiguous band of 100 MHz) to jointly increase the capacity and coverage range may raise several technical challenges, such as increasing the size of each individual channel may result in increasing the complexity of a typical receiver. The single-band solution may be obtained by adopting channel aggregation in one or more hardware units which may result in a challenging spectral efficiency (SE), since the 5G networks use a conventional filtered orthogonal frequency division multiplexing (f-OFDM) based waveform that requires guard bands. The single-band solution may also be obtained by using both the polarizations (i.e., the horizontal and the vertical polarization) for each channel, which in turn results in implementation complexity.

Currently, certain attempts have been made to obtain the single-band solution by using a conventional spectrally-localized waveform that is based on the f-OFDM. By allowing the filter length to exceed the cyclic prefix (CP) length of OFDM and designing the filter appropriately, the f-OFDM based waveform can achieve a moderate frequency localization for bandwidths as narrow as a few tens of sub-carriers while keeping the inter-symbol interference/inter-carrier interference (ISI/ICI) within an acceptable limit. While the frequency localization is achieved through filtering, the data bandwidth cannot be confined. This lack of design flexibility limits the potential spectral efficiency (SE) gains that the 5G or the upcoming beyond 5G networks require. Furthermore, the f-OFDM is partially localized in time, and hence, the filtering partially satisfies the key performance indicators (KPIs) that are set for true 5G and especially beyond 5G networks in terms of latency. Thus, there exists a technical problem of an inefficient and inadequate time-frequency localization of the conventional spectrally-localized waveform and hence, unsuitable for bands and carrier aggregation requirements performed in order to satisfy the key performance indicators that are set for true 5G and especially for beyond 5G networks.

Therefore, in light of the foregoing discussion, there exists a need to overcome the aforementioned drawbacks associated with the conventional spectrally-localized waveform.

### SUMMARY

The present disclosure provides a transmitting device, a receiving device, a communication apparatus, and methods of wireless communication. The present disclosure provides a solution to the existing problem of an inefficient and inadequate time-frequency localization of the conventional spectrally-localized waveform, which is unsuitable for bands and carrier aggregation requirements performed in order to satisfy the key performance indicators that are set for true 5G and beyond 5G networks. An objective of the present disclosure is to provide an improved transmitting device, an improved receiving device, a communication apparatus with the improved transmitting device and receiving device, and methods of wireless communication that efficiently and adequately satisfy the key performance indicators that are set for true 5G and beyond 5G networks.

One or more objectives of the present disclosure are achieved by the solutions provided in the enclosed independent claims. Advantageous implementations of the present disclosure are further defined in the dependent claims.

In an aspect, the present disclosure provides a transmitting device, comprising a data symbol generation circuit configured to generate a vector of data symbols. The transmitting device further comprises a precoding circuit configured to precode the vector of data symbols, based on a predetermined precoding matrix, to generate a precoded vector of data symbols. The predetermined precoding matrix is based on a predetermined modulation matrix. The predetermined modulation matrix is based on a predetermined plurality of discrete prolate spheroidal, DPS, sequences. The transmitting device further comprises a modulation circuit configured to modulate the precoded vector of data symbols, based on the predetermined modulation matrix, to generate a modulated precoded vector of data symbols and a transmitting circuit configured to transmit the modulated precoded vector of data symbols in a Slepian-based waveform to a receiving device.

The transmitting device transmits the modulated precoded vector of data symbols in the Slepian-based waveform that is properly localized in time and frequency domain, and, hence, suitable for bands and carrier aggregation requirements performed in order to satisfy the key performance indicators that are set for beyond 5G networks including true 5G. Indeed, the Slepian-based waveform is well localized in time and frequency. Hence, no inter-symbol-interference (ISI) is induced during transmission of the modulated precoded vector of data symbols. The use of precoding (i.e., shaping) at the transmitting device maintains the time-frequency localization property of the Slepian-based waveform. The Slepian-based waveform is free of the time-domain guard interval and, hence, manifests an improved spectral efficiency that is desirable for 5G and beyond 5G networks. Moreover, the precoding circuit enables the one-tap equalization at the receiving device. The transmitting device manifests a reduced complexity and outperforms a conventional f-OFDM system by providing higher reliability and spectral efficiency. Moreover, the transmitting device satisfies the requirements (e.g., scalable numerology) for 5G networks and beyond 5G networks.

In an implementation form, the predetermined modulation matrix comprises the plurality of DPS sequences in column vectors.

The use of the plurality of DPS sequences in modulation of the vector of data symbols provides a guard interval-free (GIF) Slepian-based waveform. Therefore, no inter-symbol interference (ISI) is induced during transmission of the Slepian-based waveform.

In a further implementation form, the plurality of DPS sequences is based on a Slepian matrix.

In a further implementation form, the plurality of DPS sequences comprises one or more eigenvectors of the Slepian matrix.

The use of the plurality of DPS sequences as the one or more eigenvectors of the Slepian matrix provides a spectrally efficient data communication.

In a further implementation form, the predetermined precoding matrix is a matrix that minimises the function ∥F^{M}−SX∥_{F}², for all matrices X such that X^{H}. X=1, where F is the discrete Fourier transform matrix, S is the predetermined modulation matrix, and where F^{H} and X^{H} designate the Hermitian of F, respectively the Hermitian of X.

In a further implementation form, the transmitting device further comprises storage means storing a plurality of precoding matrices in association with a plurality of modulation matrices, and the precoding circuit is configured to select a precoding matrix associated with the predetermined modulation matrix, and use the selected precoding matrix as the predetermined precoding matrix to generate the precoded vector of data symbols.

Storing the plurality of precoding matrices at the transmitting device and selecting the precoding matrix associated with the predetermined modulation matrix results in a low-complexity implementation of the transmitting device.

In a further implementation form, the precoding circuit is configured to precode the vector of data symbols generated by the data symbol generation circuit to generate the precoded vector of data symbols by multiplying the vector of data symbols with the predetermined precoding matrix.

The precoding (or shaping) of the vector of data symbols enables one-tap equalization at the receiving device.

In a further implementation form, the modulation circuit is further configured to modulate the precoded vector of data symbols generated by the precoding circuit to generate the modulated precoded vector of data symbols by multiplying the precoded vector of data symbols with the predetermined modulation matrix.

In a further implementation form, the data symbol generating circuit is configured to generate the vector of data symbols based on a digital modulation scheme.

In a further implementation form, the digital modulation scheme is one of a quadrature amplitude modulation of order M, or a Quadrature Phase Shift Keying.

The use of the QAM of order M or the QPSK enables transmission of larger number of data bits.

In a further implementation form, the data symbol generation circuit is further configured to execute a low-density parity-check, LDPC, channel coding to generate LDPC encoded bits before generating the vector of data symbols.

The LDPC channel coding supports detection as well as correction of transmission errors (or bit errors) generated during transmission of data over a noisy transmission channel.

In another aspect, the present disclosure provides a receiving device, comprising a receiving circuit configured to receive a Slepian-based waveform that comprises a vector of data symbols from a transmitting device. The receiving device further comprises a demodulation circuit configured to demodulate the vector of data symbols, based on a predetermined demodulation matrix. The predetermined demodulation matrix is based on a predetermined plurality of discrete prolate spheroidal, DPS, sequences, to generate a demodulated vector of data symbols. The receiving device further comprises a processing circuit configured to apply a predetermined processing matrix to the demodulated vector of data symbols, to generate a processed demodulated vector of data symbols. The receiving device further comprises an equalizer circuit configured to execute an equalization on the processed demodulated vector of data symbols to extract a vector of equalized data symbols.

The receiving device is configured to execute the equalization (e.g., one-tap equalization) for extracting the vector of equalized data symbols. The use of precoding (i.e., shaping) at the transmitting device causes diagonalization of a channel matrix, which is used for executing the one-tap equalization to extract the vector of equalized data symbols. In contrast to a conventional spectrally localized waveform based on guard interval-free (GIF)-Slepian-based waveform (SWF), where no precoding is used, the one-tap equalization can not be performed even the channel is time-invariant because the channel matrix is not diagonal. Additionally, the receiving device may be used in a single-input-single-output (SISO) transceiver or a multi-input-multi-output (MIMO) transceiver that deals with doubly selective channels. Alternatively stated, the receiving device may be used for single-band transmission as well as for multi-band transmission. The receiving device manifests a reduced complexity and outperforms the conventional f-OFDM system by providing higher reliability and spectral efficiency. Moreover, the receiving device satisfies the requirements (e.g., scalable numerology) for 5G networks and beyond 5G networks including true 5G.

In an implementation form, the predetermined demodulation matrix comprises the plurality of DPS sequences in row vectors.

The use of the plurality of DPS sequences in demodulation of the vector of data symbols provides a GIF-SWF, therefore, no inter-symbol interference (ISI) is induced during transmission of the Slepian-based waveform.

In a further implementation form, the plurality of DPS sequences is based on a Slepian matrix.

In a further implementation form, the plurality of DPS sequences comprises one or more eigen vectors of the Slepian matrix.

The use of the plurality of DPS sequences as the one or more eigen vectors of the Slepian matrix provides a spectrally efficient data communication.

In a further implementation form, the predetermined demodulation matrix is the Hermitian of a corresponding predetermined modulation matrix, and the predetermined processing matrix is the Hermitian of a matrix that minimises the function ∥F^{M}−SX∥_{F}², for all matrices X such that X^{H}. X=1, where F is the discrete Fourier transform matrix, S is the predetermined modulation matrix, and where F^{H} and X^{H} designate the Hermitian of F, respectively the Hermitian of X.

In a further implementation form, the receiving device further comprises storage means storing a plurality of processing matrices in association with a plurality of demodulation matrices, and the processing circuit is configured to select a processing matrix associated with the predetermined demodulation matrix, and to use the selected processing matrix as the predetermined processing matrix to generate the processed demodulated vector of data symbols.

Storing the plurality of processing matrices at the receiving device and selecting the processing matrix associated with the predetermined demodulation matrix results in a low-complexity implementation of the receiving device.

In a further implementation form, the processing circuit is configured to process the demodulated vector of data symbols generated by the demodulation circuit to generate the processed demodulated vector of data symbols by multiplying the demodulated vector of data symbols with the predetermined processing matrix.

In a further implementation form, the demodulation circuit is further configured to demodulate the vector of data symbols received by the receiving circuit to generate the demodulated vector of data symbols by multiplying the received vector of data symbols with the predetermined demodulation matrix.

In a further implementation form, the receiving device further comprises a low-density parity-check, LDPC, decoder configured to decode the vector of equalized data symbols generated by the equalizer circuit.

The LDPC decoder supports detection as well as correction of transmission errors (or bit errors) generated during transmission of data over a noisy transmission channel.

In yet another aspect, the present disclosure provides a communication apparatus, comprising the transmitting device and the receiving device of the present disclosure.

The communication apparatus may be used for single-band transmission as well as for multi-band transmission. The communication apparatus manifests a low-complexity implementation for a system that can be designed to deal with doubly selective channels and high mobility. The communication apparatus is configured to use the precoded Slepian-based waveform that enables one-tap equalization while eliminating the time domain guard interval. The precoded GIF-SWF is properly localized in time-frequency domain and allows the communication apparatus to get rid with ISI mitigation technique. Moreover, by virtue of the precoded GIF-SWF, the communication apparatus provides an enhanced spectral efficiency (SE) suitable for 5G networks and beyond 5G networks.

In an implementation form, the transmitting device and the receiving device form a transceiver of at least one of the following types: a single-input single-output, SISO, transceiver for doubly selective channels; and a multiple-input multiple-output, MIMO, transceiver for doubly selective channels.

The communication apparatus with the transmitting device and the receiving device can be used as either the SISO transceiver or MIMO transceiver with a low implementation complexity and improved spectral efficiency.

In yet another aspect, the present disclosure provides a method of wireless communication. The method comprises generating, by a generation circuit, a vector of data symbols and precoding, by a precoding circuit, the vector of data symbols, based on a predetermined precoding matrix, to generate a precoded vector of data symbols, the predetermined precoding matrix being based on a predetermined modulation matrix, the predetermined modulation matrix being based on a predetermined plurality of discrete prolate spheroidal, DPS, sequences. The method further comprises modulating, by a modulation circuit, the precoded vector of data symbols, based on the predetermined modulation matrix, to generate a modulated precoded vector of data symbols and transmitting, by the transmitting circuit, the precoded modulated vector of data symbols in a Slepian-based waveform to a receiving device.

The method achieves all the advantages and technical effects of the transmitting device of the present disclosure.

In yet another aspect, the present disclosure provides a method of wireless communication. The method comprises receiving, by a receiving device, a Slepian-based waveform that comprises a vector of data symbols from a transmitting device and demodulating, by a demodulation circuit, the received vector of data symbols, based on a predetermined demodulation matrix, the predetermined demodulation matrix being based on a predetermined plurality of discrete prolate spheroidal, DPS, sequences, to generate a demodulated vector of data symbols. The method further comprises applying, by a processing circuit, a predetermined processing matrix to the demodulated vector of data symbols to generate a processed demodulated vector of data symbols and executing, by an equalizer circuit, an equalization on the processed demodulated vector of data symbols to extract a vector of equalized data symbols.

The method achieves all the advantages and technical effects of the receiving device of the present disclosure.

It is to be appreciated that all the aforementioned implementation forms can be combined. It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1A is a block diagram that illustrates various exemplary components of a transmitting device, in accordance with an embodiment of the present disclosure;

FIG. 1B is a block diagram that illustrates various exemplary components of a receiving device, in accordance with an embodiment of the present disclosure;

FIG. 2 is a block diagram that illustrates various exemplary components of a communication apparatus, in accordance with an embodiment of the present disclosure;

FIG. 3 depicts generation and shaping of discrete prolate spheroidal (DPS) sequences, in accordance with an embodiment of the present disclosure;

FIG. 4 illustrates an implementation scenario of a precoded GIF-SWF, in accordance with an embodiment of the present disclosure;

FIG. 5A is a graphical representation that illustrates a full power spectral density (PSD) range of a precoded GIF-SWF system and a conventional filtered-orthogonal frequency division multiplexing (f-OFDM) system, in accordance with an embodiment of the present disclosure;

FIG. 5B is a graphical representation that illustrates spectrum confinement and gains of a precoded GIF-SWF system over a conventional f-OFDM system, in accordance with an embodiment of the present disclosure;

FIG. 6A is a graphical representation that illustrates block error rate (BLER) of a precoded GIF-SWF system and a conventional f-OFDM system, in accordance with an embodiment of the present disclosure;

FIG. 6B is a graphical representation that illustrates spectral efficiency (SE) of a precoded GIF-SWF system and a conventional f-OFDM system, in accordance with an embodiment of the present disclosure;

FIG. 7 is a graphical representation that illustrates an efficient channel matrix (Q) used in a precoded GIF-SWF system, in accordance with an embodiment of the present disclosure;

FIG. 8 is a flowchart of a method of wireless communication, in accordance with an embodiment of the present disclosure; and

FIG. 9 is a flowchart of a method of wireless communication, in accordance with another embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

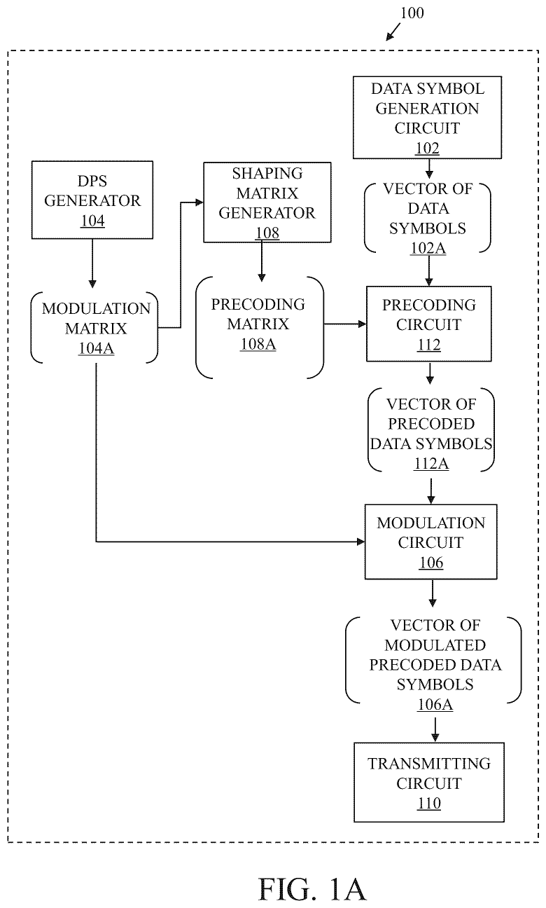

FIG. 1A is a block diagram that illustrates various exemplary components of a transmitting device, in accordance with an embodiment of the present disclosure. With reference to FIG. 1A, there is shown a block diagram of a transmitting device 100 that includes a data symbol generation circuit 102, a discrete prolate spheroidal (DPS) generator 104, a modulation circuit 106, a shaping matrix generator 108, a precoding circuit 112, and a transmitting circuit 110. The transmitting device 100 is represented by a dashed box, which is used for illustration purpose only, and does not form a part of circuitry.

The transmitting device 100 includes suitable logic, circuitry, interfaces, and/or code that is configured to generate a waveform with a time-frequency localization property that satisfies the requirements for beyond 5G networks and various design criteria. The generated waveform may also be referred to as a precoded guard interval free (GIF) Slepian-based waveform (SWF) as the transmitting device 100 uses precoding (or shaping) and discrete prolate spheroidal (DPS) sequences in modulation of a data vector. Alternatively stated, the transmitting device 100 is configured to perform a precoding (i.e., shaping) for the GIF-SWF, and the precoding scheme is performed once in offline. The transmitting device 100 may also be referred to as a transmitter or a transmitting unit that is configured for use in 5G or beyond 5G networks. Alternatively, the transmitting device 100 may be a part of another wireless communication device or other portable or non-portable communication device used for wireless communication in 5G or beyond 5G networks.

The data symbol generation circuit 102 includes suitable logic, circuitry, interfaces, and/or code that is configured to generate a vector of data symbols 102A (also represented as dₖ). In an implementation, the vector of data symbols 102A (i.e., dₖ) may include complex symbols obtained from encoded data bits. The encoded data bits are generated by virtue of using low-density parity-check (LDPC) channel coding.

The discrete prolate spheroidal (DPS) generator 104 includes suitable logic, circuitry, interfaces, and/or code that is configured to generate a plurality of DPS sequences. Alternatively stated, the DPS generator 104 may be configured to generate a plurality of modulation matrices. More specifically, the DPS generator 104 is configured to generate a predetermined modulation matrix 104A (also represented as S).

The shaping matrix generator 108 includes suitable logic, circuitry, interfaces, and/or code that is configured to generate a plurality of precoding matrices in association with the plurality of modulation matrices generated by the DPS generator 104. More specifically, the shaping matrix generator 108 is configured to generate a predetermined precoding matrix 108A (also represented as P). The predetermined precoding matrix 108A (i.e., P) may also be referred to as a shaping matrix.

The precoding circuit 112 includes suitable logic, circuitry, interfaces, and/or code that is configured to precode the vector of data symbols 102A (i.e., dₖ) using the predetermined precoding matrix 108A (i.e., P) and hence, to generate a precoded vector of data symbols 112A (also represented as P×dₖ).

The modulation circuit 106 includes suitable logic, circuitry, interfaces, and/or code that is configured to modulate the precoded vector of data symbols 112A (i.e., P×dₖ) based on the predetermined modulation matrix 104A (i.e., S) to generate a modulated precoded vector of data symbols 106A (also represented as S×P×dₖ).

The transmitting circuit 110 includes suitable logic, circuitry, interfaces, and/or code that is configured to transmit the modulated precoded vector of data symbols 106A (i.e., S×P×dₖ) in a Slepian-based waveform to a receiving device. Examples of the transmitting circuit 110 may include, but are not limited to, an antenna, a network interface, a telematics unit, or any other transmitting circuit suitable for use in the transmitting device 100, or other portable or non-portable communication devices. The transmitting circuit 110 supports various wireless communication protocols to execute wireless communication in 5G and beyond 5G networks. The receiving device is described in detail, for example, in FIG. 1B.

In operation, the transmitting device 100 comprises the data symbol generation circuit 102 configured to generate the vector of data symbols 102A. In an implementation, the vector of data symbols 102A (i.e., dₖ) may be a column vector of data symbols and the data symbols may be either binary or complex in nature.

In accordance with an embodiment, the data symbol generating circuit 102 is configured to generate the vector of data symbols 102A based on a digital modulation scheme. The vector of data symbols 102A (i.e., dₖ) is generated using the digital modulation scheme.

In accordance with an embodiment, the digital modulation scheme is one of a quadrature amplitude modulation of order M, or a Quadrature Phase Shift Keying. The digital modulation scheme is one of the quadrature amplitude modulation of order M (QAM-M), or the Quadrature Phase Shift Keying, QPSK, or any other digital modulation scheme, such as amplitude shift keying (ASK), phase-shift keying (PSK), 8-PSK, or M-ary PSK. The transmitting device 100 is configured to use the QAM modulation. However, in another implementation, any other digital modulation scheme can be used.

In accordance with an embodiment, the data symbol generation circuit 102 is further configured to execute a low-density parity-check (LDPC) channel coding to generate LDPC encoded bits before generating the vector of data symbols 102A. Before generation of the vector of data symbols 102A (i.e., dₖ), the LDPC channel coding is implied on a raw input data (e.g., a binary data) to generate the LDPC encoded bits. Generally, the LDPC channel coding is an efficient channel coding that allows detection and correction of transmission errors (or bit errors) generated during the transmission of data over a noisy transmission channel. After the LDPC channel coding, the generated LDPC encoded bits are mapped into complex symbols that follow the digital modulation scheme, such as the QAM-M, QPSK, and the like.

The transmitting device 100 further comprises the precoding circuit 112 configured to precode the vector of data symbols 102A, based on the predetermined precoding matrix 108A, to generate the precoded vector of data symbols 112A. The predetermined precoding matrix 108A is based on the predetermined modulation matrix 104A, the predetermined modulation matrix 104A is based on a predetermined plurality of discrete prolate spheroidal, DPS, sequences. The vector of data symbols 102A (i.e., dₖ) is precoded or shaped by use of the predetermined precoding matrix 108A (i.e., P). Alternatively stated, the precoding circuit 112 is configured to generate the precoded vector of data symbols 112A using the predetermined precoding matrix 108A (i.e., P) and the vector of data symbols 102A (i.e., dₖ). The predetermined precoding matrix 108A (i.e., P) is based on the predetermined modulation matrix 104A (i.e., S) generated by the DPS generator 104. The predetermined modulation matrix 104A (i.e., S) comprises the predetermined plurality of DPS sequences generated by the DPS generator 104.

In accordance with an embodiment, the precoding circuit 112 is configured to precode the vector of data symbols 102A generated by the data symbol generation circuit 102 to generate the precoded vector of data symbols 112A by multiplying the vector of data symbols 102A with the predetermined precoding matrix 108A. The precoding circuit 112 is configured to generate the precoded vector of data symbols 112A (i.e., P×dₖ) by multiplying the vector of data symbols 102A (i.e., dₖ) with the predetermined precoding matrix 108A (i.e., P).

In accordance with an embodiment, the transmitting device 100 further comprises storage means storing a plurality of precoding matrices in association with a plurality of modulation matrices, and where the precoding circuit 112 is configured to select a precoding matrix associated with the predetermined modulation matrix 104A, and use the selected precoding matrix as the predetermined precoding matrix 108A to generate the precoded vector of data symbols 112A. The plurality of precoding matrices generated by the shaping matrix generator 108 may be stored in a look-up table. The generation of the plurality of precoding matrices may be performed in association with the plurality of modulation matrices. The look-up table is stored in the transmitting device 100. Furthermore, the precoding circuit 112 is configured to select one precoding matrix, which is associated with the predetermined modulation matrix 104A (i.e., S), from the plurality of precoding matrices stored in the look-up table. Thereafter, the selected precoding matrix is used as the predetermined precoding matrix 108A (i.e., P), which is used to generate the precoded vector of data symbols 112A (i.e., P×dₖ). The generation of the plurality of precoding matrices is performed once per quality of service session. Moreover, the computation of the plurality of precoding matrices by the shaping matrix generator 108 is performed offline and independent of the channel state information (CSI). The computation of the plurality of precoding matrices including the predetermined precoding matrix 108A (i.e., P) is exhaustive in nature, hence, computed offline. Moreover, the computation of the plurality of precoding matrices including the predetermined precoding matrix 108A (i.e., P) does not rely on any CSI, such as scattering, fading, signal decay with distance, etc., which results in a low implementation complexity of the transmitting device 100.

The transmitting device 100 further comprises the modulation circuit 106 configured to modulate the precoded vector of data symbols 112A, based on the predetermined modulation matrix 104A, to generate a modulated precoded vector of data symbols 106A. The modulation circuit 106 is configured to modulate the precoded (or shaped) vector of data symbols 112A that is precoded by the precoding circuit 112 by use of the predetermined precoding matrix 108A (i.e., P). Further, the precoded vector of data symbols 112A (i.e., P×dₖ) is modulated by use of the modulation matrix 104A (i.e., S).

In accordance with an embodiment, the modulation circuit 106 is further configured to modulate the precoded vector of data symbols 112A generated by the precoding circuit 112 to generate the modulated precoded vector of data symbols 106A by multiplying the precoded vector of data symbols 112A with the predetermined modulation matrix 104A. Alternatively stated, the modulation circuit 106 is configured to multiply the precoded vector of data symbols 112A (i.e., P×dₖ) with the predetermined modulation matrix 104A (i.e., S) in order to generate the modulated precoded vector of data symbols 106A (i.e., S×P×dₖ), where the multiplication of the predetermined modulation matrix 104A (i.e., S) and the predetermined precoding matrix 108A (i.e., P) results in a shaped modulation matrix (i.e., S). Hence, the modulated precoded vector of data symbols 106A (i.e., S×P×dₖ) may also be written as a multiplication of the shaped modulation matrix (i.e., S) and the vector of data symbols 102A (i.e., dₖ) as S×dₖ. The modulation circuit 106 may also be referred to as a flexible Slepian modulator.

In accordance with an embodiment, the predetermined modulation matrix 104A comprises the plurality of DPS sequences in column vectors. The predetermined modulation matrix 104A (i.e., S) comprises the plurality of DPS sequences arranged in column vectors. In this way, the modulation of the precoded vector of data symbols 112A using the predetermined modulation matrix 104A (i.e., S) may also be termed as a modulation using DPS sequences.

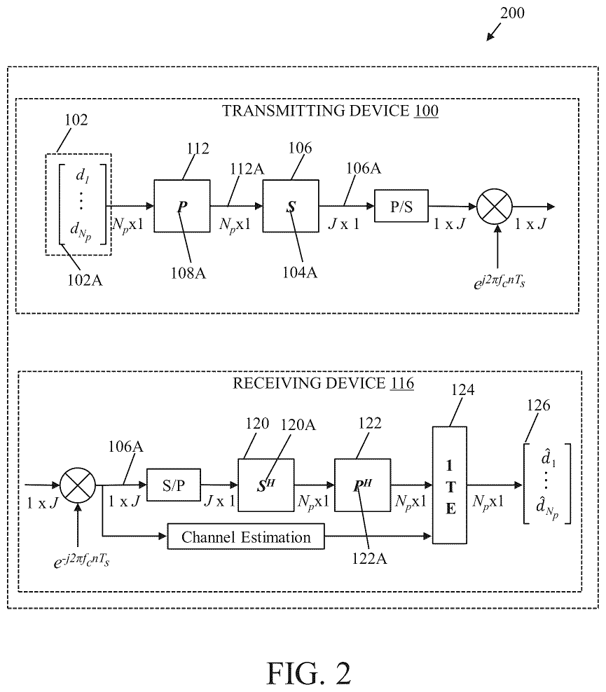

In accordance with an embodiment, the plurality of DPS sequences is based on a Slepian matrix. The DPS generator 104 is configured to generate the plurality of DPS sequences using the Slepian matrix. The Slepian matrix is described in detail, for example, in FIG. 3. The generated plurality of DPS sequences are arranged as column vectors of the predetermined modulation matrix 104A (i.e., S). Moreover, the predetermined modulation matrix 104A (i.e., S) may have one or more column vectors of the plurality of DPS sequences.

In accordance with an embodiment, the plurality of DPS sequences comprises one or more eigenvectors of the Slepian matrix. The plurality of DPS sequences is one or more eigenvectors of the Slepian matrix, which are arranged in one or more columns according to their eigen values. This is described in detail, for example, in FIG. 3.

In an example, the precoding circuit 112 can be activated or deactivated depending on a use case. When the precoding circuit 112 is activated, the precoding (or shaping) of the vector of data symbols 102A (i.e., dₖ) is performed. Additionally, the modulation circuit 106 is configured to generate the shaped modulation matrix (i.e., S) by virtue of multiplication of the predetermined modulation matrix 104A (i.e., S) and the predetermined precoding matrix 108A (i.e., P) as \tilde{S}=S×P.

However, in a case where the precoding circuit 112 is deactivated, for example, either the predetermined precoding matrix 108A (i.e., P) is not used or the predetermined precoding matrix 108A is an identity matrix (i.e., P=I), where I is an identity matrix, then, the shaped modulation matrix (i.e., S) become equal to the predetermined modulation matrix 104A (i.e., S) and hence, the transmitting device 100 may become equal to a conventional transmitting device where no precoding (or shaping) is used and therefore, the conventional transmitting device is unable to achieve the advantages due to precoding (or shaping).

Moreover, the precoding of the vector of data symbols 102A (i.e., dₖ) by the precoding circuit 112 causes a diagonalization of a channel matrix, where the diagonalization of the channel matrix is used by the receiving device to determine functions of the channel matrix to perform equalization and estimate a vector of data symbols.

The transmitting device 100 further comprises the transmitting circuit 110 configured to transmit the modulated precoded vector of data symbols 106A in a Slepian-based waveform to a receiving device. The transmitting device 100 is configured to transmit the modulated precoded vector of data symbols 106A (i.e., S×P×dₖ) to the receiving device in the Slepian-based waveform by use of the transmitting circuit 110. The Slepian-based waveform corresponds to a radio-frequency (RF) signal(s) that is transmitted to the receiving device. The Slepian-based waveform may also be referred to as a precoded Slepian-based waveform by virtue of using the predetermined precoding matrix 108A (i.e., P) and the predetermined modulation matrix 104A (i.e., S). The precoded Slepian-based waveform enables one-tap equalization at the receiving device, while eliminating the requirement of inserting a time-domain guard interval. Thus, the precoded Slepian-based waveform does not rely on any time-domain guard interval (neither a cyclic prefix (CP) nor a zero-padding (ZP)), hence, may be referred to as a precoded guard-interval-free (GIF) Slepian-based waveform (SWF). The precoded GIF-SWF is well-localized in time as well as in frequency domain and gets rid of inter-symbol-interference (ISI) mitigation technique. Thus, the precoded GIF-SWF manifests an improved spectral efficiency that is desirable to 5G and beyond 5G networks. Moreover, the Slepian-based waveform mitigates the out-of-band suppression, thus, satisfies the requirements for 5G and beyond 5G networks.

Thus, the transmitting device 100 is configured to precode or shape the vector of data symbols 102A (i.e., dₖ) by use of the predetermined precoding matrix 108A (i.e., P). Thereafter, the precoded vector of data symbols 112A (i.e., P×dₖ) is modulated by use of the predetermined modulation matrix 104A (i.e., S) and the modulated precoded vector of data symbols 106A (i.e., S×P×dₖ) is generated. Furthermore, the modulated precoded vector of data symbols 106A (i.e., S×P×dₖ) is transmitted in the Slepian-based waveform that is well localized in time and frequency hence, no ISI is induced during transmission of the modulated precoded vector of data symbols 106A (i.e., S×P×dₖ). The use of precoding (or shaping) at the transmitting device 100 maintains the time-frequency localization property of the Slepian-based waveform. The Slepian-based waveform is free of the time-domain guard interval and hence, provides an improvement in spectral efficiency that is desirable for 5G and beyond 5G networks. Moreover, the precoding circuit 112 enables the one-tap equalization at the receiving device (described in detail, for example, in FIG. 1B). Additionally, the transmitting device 100 may be used in a single-input-single-output (SISO) transceiver or a multi-input-multi-output (MIMO) transceiver that deals with doubly selective channels. The transmitting device 100 manifests a reduced complexity and outperforms the conventional f-OFDM system by providing higher reliability and improved spectral efficiency. Moreover, the transmitting device 100 satisfies the requirements (e.g., scalable numerology) for 5G networks and beyond 5G networks. The circuitry of the transmitting device 100 is compatible with multi-band hardware devices.

FIG. 1B is a block diagram that illustrates various exemplary components of a receiving device, in accordance with an embodiment of the present disclosure. FIG. 1B is described in conjunction with elements from FIG. 1A. With reference to FIG. 1B, there is shown a block diagram of a receiving device 116 that includes a receiving circuit 118, a demodulation circuit 120, a processing circuit 122, an equalizer circuit 124, a vector of equalized data symbols 126, and a low-density parity-check (LDPC) decoder 128.

The receiving device 116 includes suitable logic, circuitry, interfaces, and/or code that is configured to estimate the vector of equalized data symbols 126 by processing information received from the transmitting device 100 (of FIG. 1A). The receiving device 116 is further configured to use discrete prolate spheroidal (DPS) sequences in demodulation and one-tap equalization to estimate the vector of equalized data symbols 126 with an improved reliability and efficiency as well. The receiving device 116 may also be referred to as a receiver or a receiving unit that is configured for use in 5G or beyond 5G networks. Alternatively, the receiving device 116 may be a part of another wireless communication device or another portable or non-portable communication device used for wireless communication in 5G or beyond 5G networks.

The receiving circuit 118 includes suitable logic, circuitry, interfaces, and/or code that is configured to receive a Slepian-based waveform that comprises a vector of data symbols (i.e., the modulated precoded vector of data symbols 106A) from a transmitting device (e.g., the transmitting device 100, of FIG. 1A). Examples of the receiving circuit 118 may include, but are not limited to, an antenna, a radio frequency transceiver, a network interface, a telematics unit, or any other receiving circuit suitable for use in the receiving device 116, or other portable or non-portable communication devices. The receiving circuit 118 supports various wireless communication protocols to execute wireless communication, for example, in 5G and beyond 5G networks.

The demodulation circuit 120 includes suitable logic, circuitry, interfaces, and/or code that is configured to demodulate the vector of data symbols (i.e., the modulated precoded vector of data symbols 106A) based on a predetermined demodulation matrix 120A (also represented as S^{H}) and generate a demodulated vector of data symbols.

The processing circuit 122 includes suitable logic, circuitry, interfaces, and/or code that is configured to apply a predetermined processing matrix 122A (also represented as P^{H}) to the demodulated vector of data symbols, to generate a processed demodulated vector of data symbols.

The equalizer circuit 124 includes suitable logic, circuitry, interfaces, and/or code that is configured to execute an equalization on the processed demodulated vector of data symbols to extract the vector of equalized data symbols 126.

The LDPC decoder 128 includes suitable logic, circuitry, interfaces, and/or code that is configured to decode the vector of equalized data symbols 126.

In operation, the receiving device 116 comprises the receiving circuit 118 configured to receive the Slepian-based waveform that comprises the vector of data symbols, from the transmitting device 100. The receiving circuit 118 of the receiving device 116 is configured to receive the Slepian-based waveform as a radio frequency (RF) signal from the transmitting device 100 (of FIG. 1A). The received Slepian-based waveform comprises the vector of data symbols (i.e., the modulated precoded vector of data symbols, 106A, S×P×dₖ).

The receiving device 116 further comprises the demodulation circuit 120 configured to demodulate the vector of data symbols, based on the predetermined demodulation matrix 120A. The predetermined demodulation matrix 120A is based on a predetermined plurality of discrete prolate spheroidal, DPS, sequences, to generate a demodulated vector of data symbols. The demodulation circuit 120 is configured to demodulate the vector of data symbols (i.e., the modulated precoded vector of data symbols, 106A, S×P×dₖ) using the predetermined demodulation matrix 120A (i.e., S^{H}) in order to generate the demodulated vector of data symbols (i.e., the demodulated precoded vector of data symbols). The predetermined demodulation matrix 120A (i.e., S^{H}) comprises the predetermined plurality of DPS sequences. Alternatively stated, the demodulation circuit 120 of the receiving device 116 is configured to use the plurality of DPS sequences in demodulation of the vector of data symbols.

In accordance with an embodiment, the demodulation circuit 120 is further configured to demodulate the vector of data symbols received by the receiving circuit 118 to generate the demodulated vector of data symbols by multiplying the received vector of data symbols with the predetermined demodulation matrix 120A. For demodulation of the vector of data symbols (i.e., the modulated precoded vector of data symbols, 106A, S×P×dₖ), which is received by the receiving circuit 118, the demodulation circuit 120 of the receiving device 116 is configured to multiply the received vector of data symbols with the predetermined demodulation matrix 120A and generate the demodulated vector of data symbols (i.e., the demodulated precoded vector of data symbols).

In accordance with an embodiment, the predetermined demodulation matrix 120A comprises the plurality of DPS sequences in row vectors. The predetermined demodulation matrix 120A (i.e., S^{H}) comprises the plurality of DPS sequences which may be arranged in one or more row vectors. In this way, the demodulation of the vector of data symbols using the predetermined demodulation matrix 120A (i.e., S^{H}) may also be termed as a demodulation using DPS sequences.

In accordance with an embodiment, the plurality of DPS sequences is based on a Slepian matrix. The DPS generator 104 is configured to generate the plurality of DPS sequences using the Slepian matrix. The Slepian matrix is described in detail, for example, in FIG. 3. The generated plurality of DPS sequences are arranged as row vectors of the predetermined demodulation matrix 120A (i.e., S^{H}).

In accordance with an embodiment, the plurality of DPS sequences comprises one or more eigenvectors of the Slepian matrix. The plurality of DPS sequences comprises one or more eigenvectors of the Slepian matrix, which are arranged in one or more rows according to their eigen values.

The receiving device 116 further comprises the processing circuit 122 configured to apply the predetermined processing matrix 122A to the demodulated vector of data symbols, to generate the processed demodulated vector of data symbols. The processing circuit 122 is configured to process the demodulated vector of data symbols (i.e., the demodulated precoded vector of data symbols) using the predetermined processing matrix 122A (i.e., P^{H}) in order to generate the processed demodulated vector of data symbols (i.e., the demodulated decoded vector of data symbols).

In accordance with an embodiment, the processing circuit 122 is configured to process the demodulated vector of data symbols generated by the demodulation circuit 120 to generate the processed demodulated vector of data symbols by multiplying the demodulated vector of data symbols with the predetermined processing matrix 122A. For generation of the vector of processed demodulated data symbols, the processing circuit 122 of the receiving device 116 is configured to multiply the vector of demodulated data symbols generated by the demodulation circuit 120 with the predetermined processing matrix 122A.

In accordance with an embodiment, the predetermined demodulation matrix 120A is the Hermitian of a corresponding predetermined modulation matrix, and the predetermined processing matrix 122A is the Hermitian of a matrix that minimises the function ∥F^{M}−SX∥_{F}², for all matrices X such that X^{H}. X=1, where F is the discrete Fourier transform matrix, S is the predetermined modulation matrix, and where F^{H} and X^{H} designate the Hermitian of F, respectively the Hermitian of X. For example, the predetermined demodulation matrix 120A (i.e., S^{H}) is the Hermitian of the predetermined modulation matrix 104A (i.e., S). Alternatively, it may be stated, the demodulation circuit 120 is configured to apply the Hermitian (or the Hermitian function) on the predetermined modulation matrix 104A (i.e., S) to generate the predetermined demodulation matrix 120A (i.e., S^{H}). Similarly, the predetermined processing matrix 122A (i.e., P^{H}) is the Hermitian of the predetermined precoding matrix 108A (i.e., P), which is a matrix that minimises the function ∥F^{H}−SX∥_{F}², for all matrices X such that X^{H}. X=1, where F is the discrete Fourier transform matrix, S is the predetermined modulation matrix 104A, and F^{H} and X^{H} designate the Hermitian of F and the Hermitian of X, respectively. Generally, the Hermitian function (or transpose-conjugate) may be defined as a complex function with the characteristic that its complex conjugate is equal to an original function with the variables changed in sign.

In accordance with an embodiment, the receiving device 116 further comprises storage means storing a plurality of processing matrices in association with a plurality of demodulation matrices, and where the processing circuit 122 is configured to select a processing matrix associated with the predetermined demodulation matrix 120A, and to use the selected processing matrix as the predetermined processing matrix 122A to generate the vector of processed demodulated data symbols. The plurality of processing matrices may be stored in a look-up table in association with the plurality of demodulation matrices. The look-up table is stored in the receiving device 116. Furthermore, the processing circuit 122 is configured to select one processing matrix from the plurality of processing matrices stored in the look-up table, which is associated with the predetermined demodulation matrix 120A (i.e., S^{H}). Thereafter, the selected processing matrix is used as the predetermined processing matrix 122A (i.e., P^{H}), which is used to generate the vector of processed demodulated data symbols. The generation of the plurality of processing matrices is performed once per quality of service session. Moreover, the computation of the plurality of processing matrices is performed offline and independent of CSI. The computation of the plurality of processing matrices including the predetermined processing matrix 122A (i.e., P^{H}) is exhaustive in nature, hence, computed offline.

The receiving device 116 further comprises the equalizer circuit 124 configured to execute an equalization on the processed demodulated vector of data symbols to extract the vector of equalized data symbols 126. The equalizer circuit 124 of the receiving device 116 s configured to execute the equalization (e.g., one-tap equalization) on the processed demodulated vector of data symbols in order to extract the vector of equalized data symbols 126. The equalizer circuit 124 is configured to perform the equalization (i.e., one-tap equalization) on the processed demodulated vector of data symbols based on channel estimation. Generally, the one-tap equalization refers to delaying a signal by one sampling unit. If the signal is passed through a shift register (or memory), each ‘tap’ of the register represents a unit delay. The vector of equalized data symbols 126 may also be referred to as an estimated version of the vector of data symbols 102A (i.e., dₖ) generated at the transmitting device 100. In an implementation, the equalizer circuit 124 may be configured to determine functions of an effective channel matrix (also represented as Q) that is a diagonal matrix. The channel matrix is generated at the receiving device 116 based on the channel estimation, that is used to execute the equalization (i.e., one-tap equalization) in order to extract the vector of equalized data symbols 126. Moreover, the precoding (or shaping) used at the transmitting device 100 results in diagonalization of the effective channel matrix, which is further used to execute the equalization.

In accordance with an embodiment, the receiving device 116 further comprises a low-density parity-check (LDPC) decoder 128 configured to decode the vector of equalized data symbols 126 generated by the equalizer circuit 124. The vector of equalized data symbols is decoded by use of the LDPC decoder 128. In an implementation, the vector of equalized data symbols may be decoded to binary data by use of the LDPC decoder 128.

Thus, the receiving device 116 is configured to execute the equalization for extracting the vector of equalized data symbols 126 by virtue of the equalizer circuit 124. The use of precoding (or shaping) at the transmitting device 100 causes diagonalization of the channel matrix, which is used for executing the equalization to extract the vector of equalized data symbols 126. In contrast to conventional spectrally localized waveform based on GIF-SWF where no precoding is used, the one-tap equalization can not be performed even the channel is time-invariant because the channel matrix is not diagonal. Additionally, the receiving device 116 may be used in a single-input-single-output (SISO) transceiver or a multi-input-multi-output (MIMO) transceiver that deals with doubly selective channels. Alternatively stated, the receiving device 116 may be used for single-band transmission as well as for multi-band transmission. The receiving device 116 manifests the least complexity and outperforms the conventional f-OFDM system by providing higher reliability and improved spectral efficiency. Moreover, the receiving device 116 satisfies the requirements (e.g., scalable numerology) for 5G networks and beyond 5G networks.

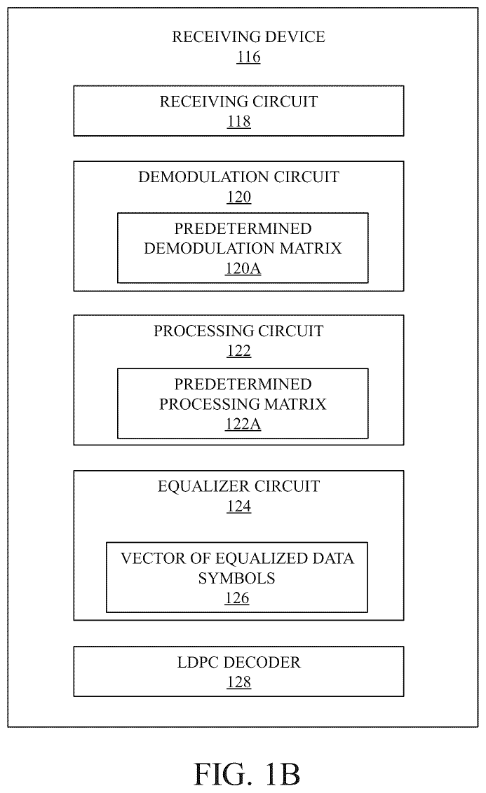

FIG. 2 is a block diagram that illustrates various exemplary components of a communication apparatus, in accordance with an embodiment of the present disclosure. FIG. 2 is described in conjunction with elements from FIGS. 1A, and 1B. With reference to FIG. 2, there is shown a block diagram of a communication apparatus 200 that includes the transmitting device 100 (of FIG. 1A) and the receiving device 116 (of FIG. 1B). Each of the transmitting device 100 and the receiving device 116 is represented by a dashed box, which is used for illustration purpose only and does not form a part of circuitry.

The communication apparatus 200 comprising the transmitting device 100 and the receiving device 116 and fulfills the requirements of 5G networks and beyond 5G networks by providing reliable and fast wireless communication with an improved spectral efficiency. The communication apparatus 200 may be used for single-band transmission as well as for multi-band transmission. Examples of the communication apparatus 200 include, but are not limited to, a transceiver, single-input-single-output (SISO) transceiver, multiple-input-multiple-output (MIMO) transceiver, a base station, a user equipment, and the like.

In operation, at the transmitting device 100 of the communication apparatus 200, the data symbol generation circuit 102 is configured to generate the vector of data symbols 102A (also represented by [d₁, . . . , d_{N}_{ₚ}], dₖ). Before the generation of the vector of data symbols 102A (i.e., [d₁, . . . , d_{N}_{ₚ}], dₖ), the LDPC channel coding is implied on a raw input data (e.g., a binary data) to generate the LDPC encoded bits. After the LDPC channel coding, the generated LDPC encoded bits are mapped into Nₚ complex symbols following the digital modulation scheme, for example, the QAM-M, or the QPSK and stack into the vector of data symbols 102A (i.e., dₖ). The vector of data symbols 102A (i.e., dₖ) may be a column vector having dimensions Nₚ×1. After the generation of the vector of data symbols 102A (i.e., dₖ), the vector of data symbols 102A (i.e., dₖ) is precoded (or shaped) by using the predetermined precoding matrix 108A (i.e., P), which is applied by the precoding circuit 112. By virtue of precoding (or shaping), the precoded vector of data symbols 112A (i.e., P×dₖ) is generated, which have a dimensions of N_{P}×1. After precoding, the precoded vector of data symbols 112A is modulated using the predetermined modulation matrix 104A (i.e., S) applied by the modulation circuit 106 in order to generate the modulated precoded vector of data symbols 106A (i.e., S×P×dₖ). Alternatively stated, the modulation of the precoded vector of data symbols 112A is performed using the plurality of DPS sequences comprised by the predetermined modulation matrix 104A (i.e., S). The plurality of DPS sequences'generation is described in detail, for example, in FIG. 3. After precoding and DPS modulation, the modulated precoded vector of data symbols 106A (i.e., S×P×dₖ) is generated that may have dimensions of J×1, where J is the number of samples. Thereafter, the dimensions of the modulated precoded vector of data symbols 106A (i.e., S×P×dₖ) is changed from J×1 to 1×J by use of a parallel-to-serial (P/S) converter. The modulated precoded vector of data symbols 106A (i.e., S×P×dₖ) is transformed into a Slepian-based waveform (SWF) by use of a matrix E. Alternatively stated, the matrix E is used for transforming the modulated precoded vector of data symbols 106A (i.e., S×P×dₖ) from baseband to the Slepian-based waveform (SWF) or a radio-frequency (RF) signal. The Slepian-based waveform (SWF) is transmitted by the transmitting circuit 110 of the transmitting device 100. In this way, a transmitted vector of data symbols, which may also be termed as a k-th GIF-SWF transmitted symbol, is given by equation (1)

$${x}_{k} = E \tilde{S} {d}_{k} \qquad ( 1 )$$

$$where {d}_{k} = {[ {d}_{k , 1} … {d}_{k , {N}_{P}} ]}^{T} , E = diag \{ {e}^{j 2 π {f}_{c} n} , n ∈ [ J , J - 1 ] \} and {x}_{k} [ n ] = {\sum }_{p = I}^{{N}_{p}} {d}_{k , p} \tilde{S} [ n , p ] {e}^{j 2 π {f}_{c} n} .$$

The transmitted vector of data symbols (or a time-domain symbol) in form of the Slepian-based waveform (or the RF signal) is received by the receiving circuit 118 of the receiving device 116 and is represented by equation (2)

$${r}_{k} = HE \tilde{S} {d}_{k} + {H}_{1} E \tilde{S} {d}_{k - 1} + η \qquad ( 2 )$$

where H is a J×J lower triangular time-varying channel matrix, H₁ is a J×J upper triangular time-varying channel matrix that represents ISI, dₖ₋₁ is a previous data vector and n is a J×1 additive white Gaussian noise (AWGN) vector. The received time domain symbol corresponds to the Slepian-based waveform that comprises a vector of data symbols (i.e., the modulated precoded vector of data symbols 106A, S×P×dₖ) of dimensions 1×J transmitted by the transmitting device 100. After receiving the vector of data symbols (i.e., the modulated precoded vector of data symbols 106A, S×P×dₖ), a serial-to-parallel (S/P) converter is used to change the dimensions of the vector of data symbols from 1×J to J×1. After serial-to-parallel (S/P) conversion, the vector of data symbols is demodulated by using the predetermined demodulation matrix 120A (i.e., S^{H}) generated by the demodulation circuit 120. The predetermined demodulation matrix 120A (i.e., S^{H}) is used to demodulate the vector of data symbols to generate a demodulated vector of data symbols (i.e., the demodulated precoded vector of data symbols). At the receiving device 116, the demodulated vector of data symbols is represented by the equation (3)

$${y}_{k} = {\tilde{S}}^{H} {E}^{H} {r}_{k} = {\tilde{S}}^{H} {E}^{H} HE \tilde{S} {d}_{k} + {\tilde{S}}^{H} {E}^{H} {H}_{I} E \tilde{S} {d}_{k - 1} + {\tilde{S}}^{H} {E}^{H} η \qquad ( 3 )$$

where, \tilde{S}^{H}=P^{H}S^{H} is a matrix having shaped DPS sequences in its rows. Consequently, ñ=\tilde{S}^{H}E^{H}η is a AWGN vector with covariance matrix σ²I where I is an N_{P}×N_{P} identity matrix. The effective channels are represented by the channel matrices as Q=\tilde{S}^{H}E^{H}HᵢE\tilde{S} and Q=\tilde{S}^{H}E^{H}H¹E\tilde{S} where the effective channel matrix Q=\tilde{S}^{H}E^{H} H₁E\tilde{S} represents ISI.

It is to be noted that ISI cancellation techniques are not used at the receiving device 116.

After demodulation, the processing circuit 122 is configured to apply the predetermined processing matrix 122A (i.e., P^{H}) to process the demodulated vector of data symbols in order to generate a processed demodulated vector of data symbols. After processing by the processing circuit 122, the equalizer circuit 124 is configured to execute an equalization (i.e., one-tap equalization) on the processed demodulated vector of data symbols to extract the vector of equalized data symbols 126. The equalization (i.e., the one-tap equalization) applied to the processed demodulated vector of data symbols is given by equation (4)

$$= \frac{{Q ( k , k )}^{*}}{{\vert Q ( k , k ) \vert}^{2} + {ρ}_{k} + {δ}_{k} + {σ}^{2}} {y}_{k} \qquad ( 4 )$$

$$where , {ρ}_{k} = {\sum }_{n} {\vert {Q}_{I} ( k , n ) \vert}^{2} and {δ}_{k} = {\sum }_{n \neq k} {\vert Q ( k , n ) \vert}^{2}$$

The vector of equalized data symbols 126 are given by equation (5)

$$= {μ}_{k} {d}_{k} + {ζ}_{k} k = 0 , … , {N}_{p} - 1 \qquad ( 5 )$$

where,

$${μ}_{k} = \frac{{\vert Q ( k , k ) \vert}^{2}}{{\vert Q ( k , k ) \vert}^{2} + {ρ}_{k} + {δ}_{k} + {σ}^{2}} ,$$

and ξₖ is an AWGN vector with a variance of σₖ²=μₖ−μₖ².

After the equalization, the LDPC decoder 128 is used to decode the vector of equalized data symbols 126. After LDPC decoding, errors are computed on comparison of the vector of data symbols 102A (i.e., dₖ) generated at the transmitting device 100 and the vector of equalized data symbols 126 estimated at the receiving device 116. The errors are computed by computing a log-likelihood ratio (LLR) of the i-th bit of the z-th complex sample in the transmit vector dₖ according to equation (6)

$$L L R ( {b}_{k , z , i} ) \approx \frac{1}{{σ}_{k , z}^{2}} ( {min}_{{b}_{k , z} {ϵℬ}_{i}^{-}} {\vert - {μ}_{k , z} d ( {b}_{k , z} ) \vert}^{2} - {min}_{{b}_{k , z} {ϵℬ}_{i}^{+}} {\vert - {μ}_{k , z} d ( {b}_{k , z} ) \vert}^{2} ) \qquad ( 6 )$$

where, b_{k,z}∈{−1, +1}^{m} is a binary vector, d(b_{k,z}) is the symbol mapping (e.g., 2^{m}− QAM) and Bᵢ⁺ (resp. Bᵢ⁻) is a set of all vectors b_{k,z} with <<+1>> (resp. <<−1>>) in their i-th entry.

In case, when the quadrature phase-shift keying (QPSK) is used for mapping, then exact LLR is given by equation (7) and equation (8)

$$L L R ( {b}_{k , z , 0} ) = \frac{2 \sqrt{2}}{1 - {μ}_{k , z}} ℛ \{ \} \qquad ( 7 )$$

$$L L R ( {b}_{k , z , 1} ) = \frac{2 \sqrt{2}}{1 - {μ}_{k , z}} 𝒥 \{ \} \qquad ( 8 )$$

Thus, the communication apparatus 200 may be used for single-band transmission as well as for multi-band transmission. The communication apparatus 200 manifests low implementation complexity and can be designed to deal with doubly selective channels with high mobility. The communication apparatus 200 is configured to use the precoded Slepian-based waveform that enables one-tap equalization while eliminating the time domain guard interval. The precoded GIF-SWF is properly localized in time-frequency domain and allows the communication apparatus 200 to get rid with ISI mitigation technique. Moreover, by virtue of the precoded GIF-SWF, the communication apparatus 200 provides an enhanced spectral efficiency (SE) suitable for 5G networks and beyond 5G networks.

In accordance with an embodiment, the transmitting device 100 and the receiving device 116 form a transceiver of at least one of the following types: a single input single output, SISO, transceiver for doubly selective channels; and a multiple input multiple output, MIMO, transceiver for doubly selective channels. The communication apparatus 200 with the transmitting device 100 and the receiving device 116, may be used either as the SISO transceiver for doubly selective channels for single band transmission or as the MIMO transceiver for doubly selective channels for multi-band transmission with a significantly reduced complexity.

FIG. 3 depicts generation and shaping of discrete prolate spheroidal (DPS) sequences, in accordance with an embodiment of the present disclosure. FIG. 3 is described in conjunction with elements from FIGS. 1A, 1B, and 2. With reference to FIG. 3, there is shown a block diagram 300 that illustrates generation and shaping of the DPS sequences. The block diagram 300 includes the DPS generator 104, the shaping matrix generator 108, and the modulation circuit 106.

The DPS generator 104 is configured to generate the plurality of DPS sequences based on a Slepian matrix (also denoted as C). The Slepian matrix (C) uses various parameters for generation of the plurality of DPS sequences in various steps, which are described as:

Having a frequency band Bₛ with a central frequency f_{c}.

Choose N_{P} (orthonormal) DPS sequences of length T=JTₛ with confined energy in Bₛ given by the first Nₚ eigen vectors of the Slepian matrix (C) whose elements are given by equation (9)

$$C [ p , q ] = \frac{sin ( π {B}_{s} {T}_{s} ( p - q ) )}{π ( p - q )} , ( p , q ) ∈ {\{ 1 , … , J \}}^{2} \qquad ( 9 )$$

The eigenvalue decomposition of the Slepian matrix (C) given by C=UDU^{H}, the columns of matrix U where the eigen vectors of Slepian matrix (C) given by {uⱼ}_{j=1, . . . , J}, the columns of matrix U and referred to as DPS and are ordered according to their eigen values λ₁≥λ₂ . . . ≥λⱼ.

The predetermined modulation matrix 104A (i.e., S) is of size J×N_{P} stacking the first N_{P} DPS sequences (or the plurality of DPS sequences).

The transmitting device 100 is configured to use the predetermined precoding matrix 108A (i.e., P) having the dimensions of Nₚ×Nₚ for precoding (or shaping) of the plurality of DPS sequences. The predetermined precoding matrix 108A is generated in association with the predetermined modulation matrix 104A (i.e., S) by the shaping matrix generator 108. The receiving device 116 uses the predetermined demodulation matrix 120A (i.e., S^{H}) with dimensions N_{P}×J and the predetermined processing matrix 122A (i.e., P^{H}) for demodulation and processing of the modulated precoded vector of data symbols 106A (i.e., S×P×dₖ) in the frequency band Bₛ.

The DPS sequences' duration is T=JTₛ and Tₛ is the sampling time. The multiplication of the predetermined modulation matrix 104A (i.e., S) and the predetermined precoding matrix 108A (i.e., P) results into a shaped modulation matrix 302 (i.e., \tilde{S}). The shaped modulation matrix 302 (i.e., \tilde{S}) is given as \tilde{S}=SₖP, where the index k is dropped which refers to the flexibility of the predetermined modulation matrix 104A (i.e., S) to the assigned data throughput.

The predetermined precoding matrix 108A (i.e., P, or DPS shaping matrix) provides a solution of equation (10)

$$P = arg {min}_{X} {‖ {F}^{H} - SX ‖}_{F}^{2} \qquad ( 10 )$$

$$s . t . {X}^{H} X = I$$

where F^{H} is the J×Nₚ inverse discrete Fourier transform (IDFT) matrix. Consequently, the solution of equation 10 (which is an optimization problem) is given by P=V₂V₁^{H} where V₁ and V₂ are obtained using singular value decomposition (SVD) of FS such that FS=V₁ΔV₂^{H}. Therefore, the predetermined precoding matrix 108A (i.e., P) can be computed offline and the computation does not depend on the CSI.

In accordance with an embodiment, the predetermined precoding matrix 108A is a matrix that minimises the function ∥F^{H}−SX∥_{F}², for all matrices X such that X^{H}. X=1, where F is the discrete Fourier transform matrix, S is the predetermined modulation matrix 104A, and where F^{H} and X^{H} designate the Hermitian of F, respectively the Hermitian of X.

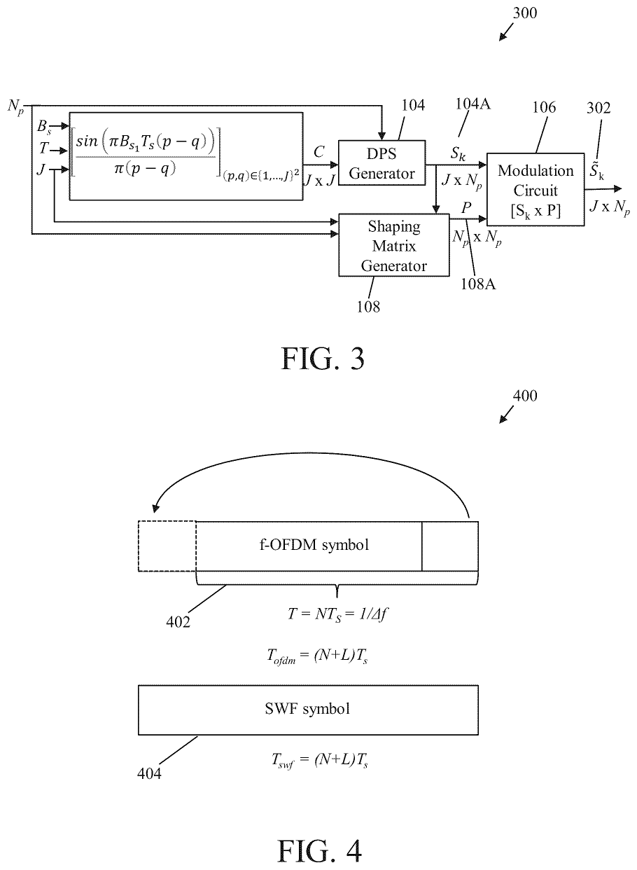

FIG. 4 illustrates an implementation scenario of a precoded guard interval free (GIF)-Slepian based waveform (SWF), in accordance with an embodiment of the present disclosure. FIG. 4 is described in conjunction with elements from FIGS. 1A, 1B, 2, and 3. With reference to FIG. 4, there is shown an implementation scenario 400 of a precoded GIF-SWF in third-generation partnership project (3GPP) channels. The implementation scenario 400 includes a filtered OFDM (f-OFDM) symbol 402 and a precoded GIF-SWF symbol 404.

A downlink (DL) channel where a conventional f-OFDM system is transmitting over 20 MHz using 106 resource blocks is considered for performance evaluation of the conventional f-OFDM system as well as the precoded GIF-SWF waveform system. For the conventional f-OFDM system, Nₐ=1272 data (active) subcarriers with a fast Fourier transform (FFT) size N_{FFT}=2048 and subcarrier spacing δf=15 kHz is considered. Hence, the sampling frequency should be set to fₛ=7.68 MHz, and a cyclic prefix (CP) of length L=144 is considered. The conventional f-OFDM filter is given by equation (11)

$$f [ n ] = \frac{sin ( {w}_{c} n )}{{w}_{c} n} {( \frac{1}{2} - \frac{1}{2} cos ( \frac{2 π n}{{L}_{f} - 1} ) )}^{0.6} \qquad ( 11 )$$

where L_{f}=1025 and w_{c}=1.9589 is the normalized cut-off frequency. Furthermore, the QPSK and QAM-16 symbols are considered for transmission using a carrier frequency f_{c}=4 GHz and the LDPC code rate of ½.

For performance comparison between the conventional f-OFDM system and the precoded GIF-SWF system, the precoded GIF-SWF symbol 404 duration should be set equal to the f-OFDM symbol 402 duration T_{ofdm}=T_{swf}=71.36 μs.

The duration of a data symbol is given by equation (12)

$$T = {NT}_{s} = \frac{1}{Δ f} \qquad ( 12 )$$

Therefore, the duration of the f-OFDM symbol 402 is given by equation (13)

$${T}_{{ofdm}^{}} = ( N + L ) {T}_{s} \qquad ( 13 )$$

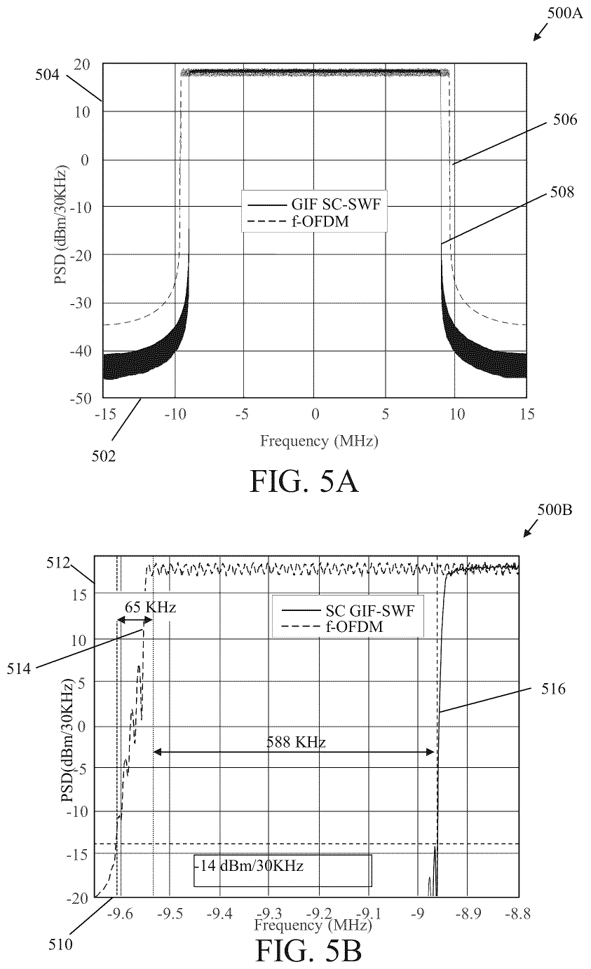

Similarly, the duration of the precoded GIF-SWF symbol 404 is given by equation (14)

$${T}_{swf} = ( N + L ) {T}_{s} \qquad ( 14 )$$

where J=N+L. For the precoded GIF-SWF, the same data rate is considered as for the conventional f-OFDM system, N_{P}=1272. The power spectral densities (PSD) associated with the precoded GIF-SWF system and the conventional f-OFDM system is depicted in FIGS. 5A, and 5B, respectively.

FIG. 5A is a graphical representation that illustrates a full power spectral density (PSD) range of a precoded GIF-SWF and a conventional filtered-orthogonal frequency division multiplexing (f-OFDM) system, in accordance with an embodiment of the present disclosure. FIG. 5A is described in conjunction with elements from FIGS. 1A, 1B, 2, 3, and 4. With reference to FIG. 5A, there is shown a graphical representation 500A that depicts a full PSD range of the precoded GIF-SWF waveform and the conventional f-OFDM system. The graphical representation 500A includes a X-axis 502 that represents frequency in megahertz (MHz). The graphical representation 500A further includes a Y-axis 504 that represents PSD in dBm over 30 KHz (dBm/30 KHz).

With reference to the graphical representation 500A, there is shown a first curve 506 that illustrates full PSD range of the conventional f-OFDM system. There is further shown a second curve 508 that illustrates full PSD range of the precoded GIF-SWF waveform (or a suppressed carrier SC GIF-SWF). The second curve 508 illustrates that the precoded GIF-SWF waveform exhibits lower out-of-band emission and hence, requires smaller spectrum guard band leading to a higher spectral efficiency than the conventional f-OFDM system.

FIG. 5B is a graphical representation that illustrates spectrum confinement and gains of a precoded GIF-SWF over a conventional f-OFDM system, in accordance with an embodiment of the present disclosure. FIG. 5B is described in conjunction with elements from FIGS. 1A, 1B, 2, 3, 4, and 5A. With reference to FIG. 5B, there is shown a graphical representation 500B that depicts spectral confinement and spectral gains of the precoded GIF-SWF waveform system over the conventional f-OFDM system. The graphical representation 500B includes a X-axis 510 that represents frequency in megahertz (MHz). The graphical representation 500B further includes a Y-axis 512 that represents PSD in dBm over (dBm/30 KHz).

With reference to the graphical representation 500B, there is shown a first spectrum 514 that depicts spectrum of the conventional f-OFDM system. There is further shown a second spectrum 516 that depicts spectrum of the precoded GIF-SWF (or the SC GIF-SWF) system. Following the 3GPP spectrum mask requirement for the downlink (described in detail, for example, in FIG. 4) channel, the conventional f-OFDM system requires 19.08 MHz to transmit data over the 106 RBs, however, the precoded GIF-SWF system requires 17.9 MHz only to transmit same data throughput. As described in the FIG. 5B, the required guard band is defined referring to the 3GPP mask requirement, which is at 14 dBm/30 KHz for the downlink (DL) providing 130 KHz and 2.7 KHz for the conventional f-OFDM system and the precoded GIF-SWF system, respectively.

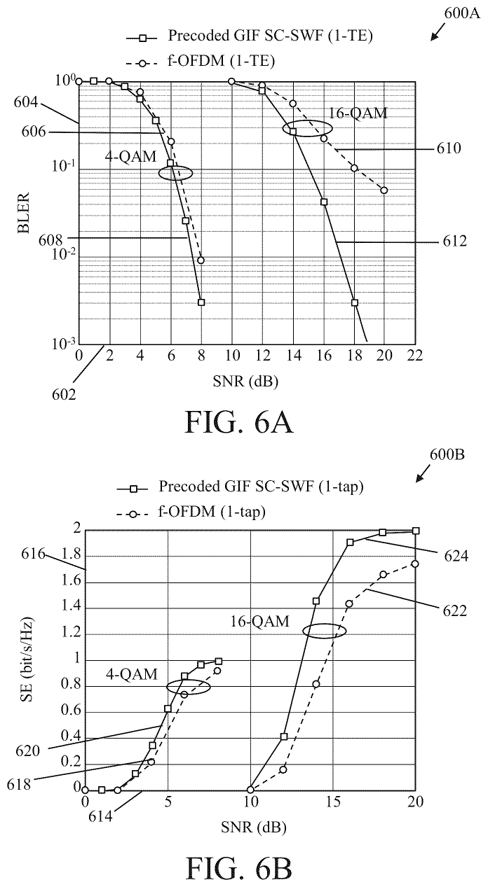

FIG. 6A is a graphical representation that illustrates block error rate (BLER) of a precoded GIF-SWF system and a conventional f-OFDM system, in accordance with an embodiment of the present disclosure. FIG. 6A is described in conjunction with elements from FIGS. 1A, 1B, 2, 3, 4, 5A, and 5B. With reference to FIG. 6A, there is shown a graphical representation 600A that depicts block error rate (BLER) of the precoded GIF-SWF waveform system and the conventional f-OFDM system. The graphical representation 600A includes a X-axis 602 that represents signal-to-ratio (SNR) in decibels (dB). The graphical representation 600A further includes a Y-axis 604 that represents block error rate (BLER).

For evaluating the performance of the precoded GIF-SWF waveform system and the conventional f-OFDM system, the tapped delay line model C (TDL-C 300 ns) channels are considered, and the performance is evaluated in terms of BLER as a function of the SNR. There is one assumption used that is the conventional f-OFDM system is using the one-tap minimum mean square error (MMSE) equalization. That means, the precoded GIF-SWF waveform system and the conventional f-OFDM system using the one-tap MMSE equalization.

With reference to the graphical representation 600A, 4-QAM and 16-QAM data symbols are considered for evaluating the BLER of the conventional f-OFDM system and the precoded GIF-SWF system. With reference to the graphical representation 600A, there is shown a first curve 606 that depicts BLER of the conventional f-OFDM system with the one-tap equalization (1-TE). There is further shown a second curve 608 that depicts BLER of the precoded GIF-SWF waveform system with the one-tap equalization. Both the first curve 606 and the second curve 608 represent the BLER with respect to the 4-QAM data symbols. Similarly, there is further shown a third curve 610 that depicts BLER of the conventional f-OFDM system with the one-tap equalization (1-TE). Furthermore, there is shown a fourth curve 612 that depicts BLER of the precoded GIF-SWF waveform system with the one-tap equalization. Both the third curve 610 and the fourth curve 612 represent the BLER with respect to the 16-QAM data symbols. The second curve 608 and the fourth curve 612 represent that the BLER of the precoded GIF-SWF system is less than that of the conventional f-OFDM system which depicts that the precoded GIF-SWF system is more reliable than that of the conventional f-OFDM system. Alternatively stated, the precoded GIF-SWF system outperforms the conventional f-OFDM system in terms of reliability while both the system uses one-tap equalization.

FIG. 6B is a graphical representation that illustrates spectral efficiency (SE) of a precoded GIF-SWF system and a conventional f-OFDM system, in accordance with an embodiment of the present disclosure. FIG. 6B is described in conjunction with elements from FIGS. 1A, 1B, 2, 3, 4, 5A, 5B, and 6A. With reference to FIG. 6B, there is shown a graphical representation 600B that depicts spectral efficiency (SE) of the precoded GIF-SWF waveform system and the conventional f-OFDM system. The graphical representation 600B includes a X-axis 614 that represents signal-to-ratio (SNR) in decibels (dB). The graphical representation 600B further includes a Y-axis 616 that represents spectral efficiency (SE) in bits/s/Hz.

For evaluating the performance of the precoded GIF-SWF waveform system and the conventional f-OFDM system, the tapped delay line model C (TDL-C 300 ns) channels are considered, and the performance is evaluated in terms of spectral efficiency (SE) as a function of the SNR. There is one assumption used that is the conventional f-OFDM system is using the one-tap minimum mean square error (MMSE) equalization. That means, the precoded GIF-SWF waveform system and the conventional OFDM system using the one-tap MMSE equalization. A very high velocity is considered where v=500 Km/h leading to a doppler frequency spread of f_{d}=1.85 KHz. The SE of the precoded GIF-SWF is given by equation (15)

$$η = \frac{χ}{T \cdot ω} = \frac{χ}{T \cdot ( {BW}_{data} + Δ {G}_{sub} )} \qquad ( 15 )$$

where χ is (TBS for 106 PRBs)×(1-simulated BLER) and TBS is transport block size.

With reference to the graphical representation 600B, 4-QAM and 16-QAM data symbols are considered for evaluating the SE of the conventional f-OFDM system and the precoded GIF-SWF system. With reference to the graphical representation 600B, there is shown a first curve 618 that depicts SE of the conventional f-OFDM system with the one-tap equalization (1-TE). There is further shown a second curve 620 that depicts SE of the precoded GIF-SWF waveform system with the one-tap equalization. Both the first curve 618 and the second curve 620 represent the SE with respect to the 4-QAM data symbols. Similarly, there is further shown a third curve 622 that depicts SE of the conventional f-OFDM system with the one-tap equalization (1-TE). Furthermore, there is shown a fourth curve 624 that depicts SE of the precoded GIF-SWF waveform system with the one-tap equalization. Both the third curve 622 and the fourth curve 624 represent the SE with respect to the 16-QAM data symbols. The second curve 620 and the fourth curve 624 represent that the SE of the precoded GIF-SWF system is higher than that of the conventional f-OFDM system which depicts that the precoded GIF-SWF system is more spectrally efficient than that of the conventional f-OFDM system. For example, a SE gain of 35% can be obtained at the SNR of 16 dB for the precoded GIF-SWF waveform system. Alternatively stated, the precoded GIF-SWF system outperforms the conventional f-OFDM system in terms of spectral efficiency gain while both the system uses one-tap equalization. Thus, the precoded GIF-SWF system efficiently boosts up the performance of a transceiver (e.g., the communication apparatus 200) while keeping low complexity of the receiving device 116 (of FIG. 1B).

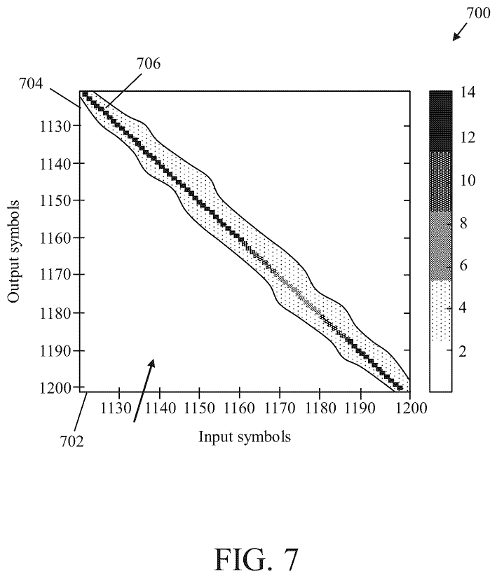

FIG. 7 is a graphical representation that illustrates an efficient channel matrix (Q) used in a precoded GIF-SWF system, in accordance with an embodiment of the present disclosure. FIG. 7 is described in conjunction with elements from FIGS. 1A, 1B, 2, 3, 4, 5A, 5B, 6A, and 6B. With reference to FIG. 7, there is shown a graphical representation 700 that depicts an efficient channel matrix (Q) used in the precoded GIF-SWF system. The graphical representation 700 includes a X-axis 702 that represents input symbols. The graphical representation 700 further includes a Y-axis 704 that represents output symbols.

With reference to the graphical representation 700, there is shown a diagonal curve 706 that represents that the effective channel matrix (Q) used in the precoded GIF-SWF system is diagonal and enables the one-tap equalization at the receiving device 116 of the communication apparatus 200 (of FIG. 2) hence, the channel matrix (Q) is termed as the efficient channel matrix. The effective channel matrix (Q) is considered in high mobility TDL C-300 ns at 500 Km/h velocity. The effective channel matrix (Q) becomes a diagonal matrix by virtue of using the precoding (or shaping) at the transmitting device 100. The precoded (or shaped) DPS sequences results in the diagonalization of the effective channel matrix (Q) thus, paving the way to the one-tap equalization. In contrast to a conventional GIF-SWF scheme where no precoding is used, the effective channel matrix (Q₁) remains non-diagonal resulting in inter-symbol interference (ISI) in the received signal, however, the Slepian-based waveform comprising the shaped DPS sequences remain well localized in time and frequency domain and hence, no ISI is induced in the precoded GIF-SWF system. Additionally, the arrow mark represents no noise in the precoded GIF-SWF system.

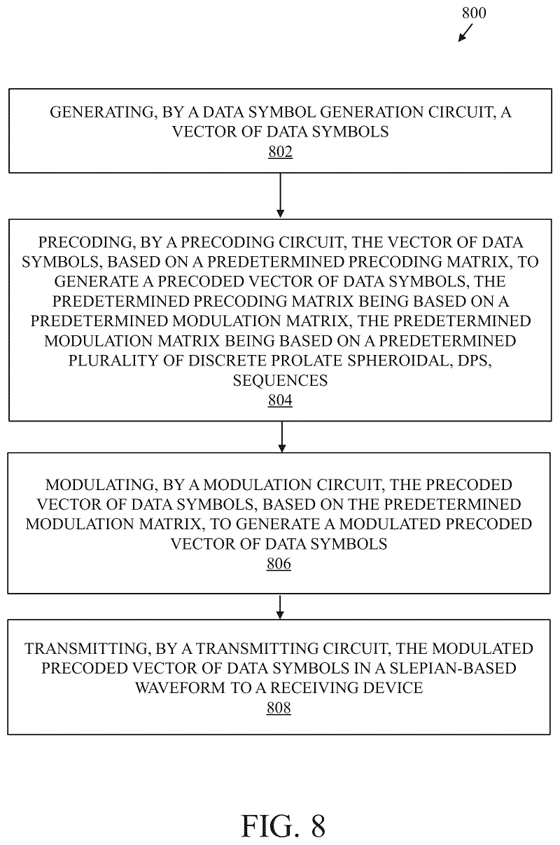

FIG. 8 is a flowchart of a method of wireless communication, in accordance with an embodiment of the present disclosure. FIG. 8 is described in conjunction with elements from FIGS. 1A, 1B, 2, and 3. With reference to FIG. 8, there is shown a method 800 of wireless communication. The method 800 includes steps 802 to 808. The method 800 may be executed by the transmitting device 100 of FIG. 1A, according to an exemplary embodiment.

At step 802, the method 800 comprises generating, by a data symbol generation circuit 102, a vector of data symbols 102A. The vector of data symbols 102A (i.e., dₖ) comprises LDPC encoded complex data symbols following the digital modulation scheme, such as the QPSK, 4-QAM, 16-QAM, M-QAM, and the like.

In accordance with an embodiment, generating the vector of data symbols 102A is based on a digital modulation scheme.

In accordance with an embodiment, the digital modulation scheme is one of a quadrature amplitude modulation of order M, or a Quadrature Phase Shift Keying. In addition to the QAM-M or QPSK, another digital modulation scheme, such as ASK, PSK, 8-PSK, 16-PSK or M-ary PSK may also be used.

In accordance with an embodiment, the method 800 further comprises executing, by the data symbol generation circuit 102, a low-density parity-check, LDPC, channel coding to generate LDPC encoded bits before generating the vector of data symbols 102A.

At step 804, the method 800 further comprises precoding, by a precoding circuit 112, the vector of data symbol 102A, based on a predetermined precoding matrix 108A, to generate a precoded vector of data symbols 112A. The predetermined precoding matrix 108A is based on a predetermined modulation matrix 104A. The predetermined modulation matrix 104A is based on a predetermined plurality of discrete prolate spheroidal, DPS, sequences. The predetermined precoding matrix 108A (i.e., P) is computed offline without depending on the channel state information. After precoding of the vector of data symbols 102A (i.e., dₖ) using the predetermined precoding matrix 106A (i.e., P), the precoded vector of data symbols 112A is generated. The predetermined precoding matrix 108A (i.e., P) is generated using the predetermined modulation matrix 104A (i.e., S). The predetermined modulation matrix 104A (i.e., S) comprises the plurality of DPS sequences in column vectors.

In accordance with an embodiment, precoding the generated vector of data symbols 102A to generate the precoded vector of data symbols 112A comprises multiplying the generated vector of data symbols 102A with the predetermined precoding matrix 108A. The precoding circuit 112 is configured to generate the precoded vector of data symbols 112A (i.e., P×dₖ) by multiplying the generated vector of data symbols 102A (i.e., dₖ) with the predetermined precoding matrix 108A (i.e., P).

In accordance with an embodiment, the predetermined precoding matrix 108A is determined by minimising the function ∥F^{H}−SX∥_{F}², for all matrices X such that X^{H}. X=1, where F is the discrete Fourier transform matrix, S is the predetermined modulation matrix 104A, and where F^{H} and X^{H} designate the Hermitian of F, respectively the Hermitian of X.

In accordance with an embodiment, a plurality of precoding matrices are predetermined and stored in storage means in the transmitting device 100, in association with the plurality of modulation matrices, such as a look-up table, and the method 800 further comprises selecting, by the precoding circuit 112, a precoding matrix associated with the predetermined modulation matrix 104A (i.e., S) in the storage means, and using, by the precoding circuit 112, the selected precoding matrix as the predetermined precoding matrix 108A (i.e., P) to generate the precoded vector of data symbols 112A.

At step 806, the method 800 further comprises modulating, by a modulation circuit 106, the precoded vector of data symbols 112A, based on the predetermined modulation matrix 104A (i.e., S), to generate a modulated precoded vector of data symbols 106A (i.e., S×P×dₖ) . . . . The modulated precoded vector of data symbols 106A (i.e., S×P×dₖ) is derived from a multiplication of the predetermined modulation matrix 104A (i.e., S), the predetermined precoding matrix 108A (i.e., P), and the vector of data symbols 102A (i.e., dₖ). However, the modulated precoded vector of data symbols 106A (i.e., S×P×dₖ) may also be written as the result of a multiplication of a shaped modulation matrix 302 (i.e., S) and the vector of data symbols 102A (i.e., dₖ), the shaped modulation matrix 302 (i.e., S) resulting from the multiplication of the predetermined modulation matrix 104A (i.e., S), the predetermined precoding matrix 108A (i.e., P).

In accordance with an embodiment, modulating the precoded vector of data symbols 112A to generate the modulated precoded vector of data symbols 106A comprises multiplying the precoded vector of data symbols 112A with the predetermined modulation matrix 104A.

In accordance with an embodiment, the predetermined modulation matrix 104A (i.e., S) comprises the plurality of DPS sequences arranged in column vectors.

In accordance with an embodiment, the plurality of DPS sequences is based on a Slepian matrix.

In accordance with an embodiment, the plurality of DPS sequences comprises one or more eigenvectors of the Slepian matrix. The one or more eigenvectors of the Slepian matrix are arranged in one or more columns according to their eigen values.

At step 808, the method 800 further comprises transmitting, by the transmitting circuit 110, the modulated precoded vector of data symbols 106A in a Slepian-based waveform to a receiving device 116. The modulated precoded vector of data symbols 106A (i.e., S×P×dₖ) is converted in the Slepian-based waveform using a matrix E which is a diagonal matrix, described in detail, for example, in FIG. 2.

Thus, the method 800 achieves all the advantages and technical effects of the transmitting device 100 (of FIG. 1A).

The steps 802 and 808 are only illustrative, and other alternatives can also be provided where one or more steps are added, one or more steps are removed, or one or more steps are provided in a different sequence without departing from the scope of the claims herein.

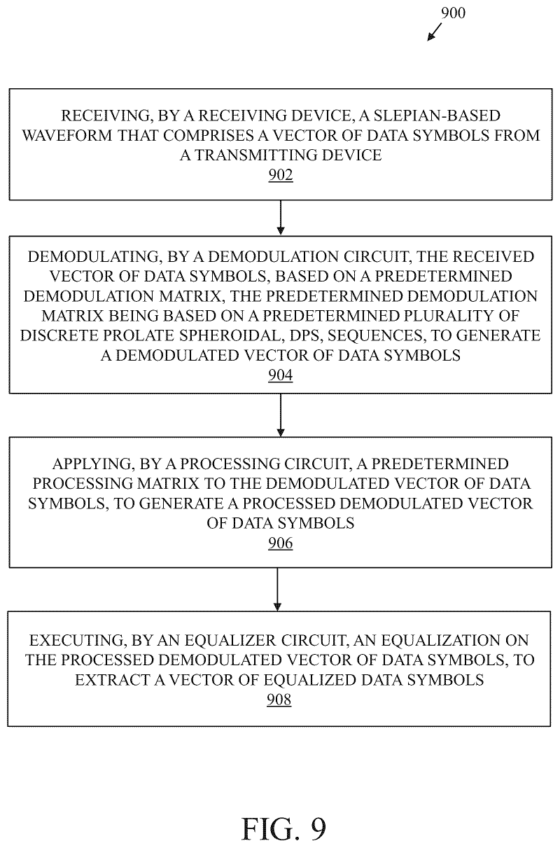

FIG. 9 is a flowchart of a method of wireless communication, in accordance with another embodiment of the present disclosure. FIG. 9 is described in conjunction with elements from FIGS. 1A, 1B, 2, 3, and 8. With reference to FIG. 9, there is shown a method 900 of wireless communication. The method 900 includes steps 902 to 908. The method 900 may be executed by the receiving device 116 of FIG. 1B, according to an exemplary embodiment.

At step 902, the method 900 comprises receiving, by a receiving device 116, a Slepian-based waveform that comprises a vector of data symbols transmitted from a transmitting device 100. The receiving circuit 118 of the receiving device 116 is configured to receive the Slepian-based waveform that comprises the vector of data symbols (i.e., the modulated precoded vector of data symbols 106A, S×P×dₖ) transmitted from the transmitting device 100.

At step 904, the method 900 further comprises demodulating, by a demodulation circuit 120, the received vector of data symbols, based on a predetermined demodulation matrix 120A. The predetermined demodulation matrix 120A is based on a predetermined plurality of discrete prolate spheroidal, DPS, sequences, to generate a demodulated vector of data symbols. After demodulation, the demodulated vector of data symbols is generated. Moreover, the predetermined demodulation matrix 120A (i.e., S^{H}) comprises the plurality of DPS sequences.

In accordance with an embodiment, the method 900 further comprises demodulating the received vector of data symbols to generate the demodulated vector of data symbols, comprises multiplying the received vector of data symbols with the predetermined demodulation matrix 120A.

In accordance with an embodiment, the predetermined demodulation matrix 120A (i.e., S^{H}) comprises the plurality of DPS sequences arranged in row vectors.

In accordance with an embodiment, the plurality of DPS sequences is based on a Slepian matrix.

In accordance with an embodiment, the plurality of DPS sequences comprises one or more eigenvectors of the Slepian matrix. The one or more eigenvectors of the Slepian matrix are arranged in one or more rows according to their eigen values.

At step 906, the method 900 further comprises applying, by a processing circuit 122, a predetermined processing matrix 122A (i.e., P^{H}) to the demodulated vector of data symbols, to generate a processed demodulated vector of data symbols. After processing, the processed demodulated vector of data symbols is generated.

In accordance with an embodiment, the method 900 further comprises applying the predetermined processing matrix 122A (i.e., P^{H}) to process the demodulated vector of data symbols generated by the demodulation circuit 120 to generate the processed demodulated vector of data symbols, which comprises multiplying the demodulated vector of data symbols with the predetermined processing matrix 122A.

In accordance with an embodiment, the predetermined demodulation matrix 120A is the Hermitian of a corresponding predetermined modulation matrix, and the predetermined processing matrix 122A is determined as being the Hermitian of a matrix that minimises the function ∥F^{H}−SX∥_{F}², for all matrices X such that X^{H}. X=1, where F is the discrete Fourier transform matrix, S is the predetermined modulation matrix 104A, and where F^{H} and X^{H} designate the Hermitian of F, respectively the Hermitian of X. For example, the predetermined demodulation matrix 120A (i.e., S^{H}) is the Hermitian of the predetermined modulation matrix 104A (i.e., S).

In accordance with an embodiment, the method 900 further comprises storing, in storage means of the receiving device 116, a plurality of processing matrices in association with a plurality of demodulation matrices, selecting, by the processing circuit 122, a processing matrix associated with the predetermined demodulation matrix 120A in said storage means, and using, by the processing circuit 122, the selected processing matrix as the predetermined processing matrix 122A to generate the processed demodulated vector of data symbols. For example, the plurality of processing matrices may be stored in a look-up table in association with the plurality of demodulation matrices, the look-up table being stored in the receiving device 116.

At step 908, the method 900 further comprises executing, by an equalizer circuit 124, an equalization on the processed demodulated vector of data symbols, to extract a vector of equalized data symbols 126. After equalization, the vector of equalized data symbols 126 is extracted.

In accordance with an embodiment, the method 900 further comprises decoding, by a low-density parity-check (LDPC) decoder 128, the vector of equalized data symbols 126. The vector of equalized data symbols 126 is decoded by use of the LDPC decoder 128. In an implementation, the vector of equalized data symbols 126 may be decoded to binary data by use of the LDPC decoder 128.

Thus, the method 900 achieves all the advantages and technical effects of the receiving device 116 (of FIG. 1B).

The steps 902 and 908 are only illustrative, and other alternatives can also be provided where one or more steps are added, one or more steps are removed, or one or more steps are provided in a different sequence without departing from the scope of the claims herein.

Modifications to embodiments of the present disclosure described in the foregoing are possible without departing from the scope of the present disclosure as defined by the accompanying claims. Expressions such as “including”, “comprising”, “incorporating”, “have”, “is” used to describe, and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the invention, which are, for brevity, described in the context of a single embodiment, may also be provided separately or in any suitable combination or as suitable in any other described embodiment of the disclosure.

1. A transmitting device comprising:
a data symbol generation circuit configured to generate a vector of data symbols;
a precoding circuit configured to precode the vector of data symbols, based on a predetermined precoding matrix, to generate a precoded vector of data symbols, the predetermined precoding matrix being based on a predetermined modulation matrix, the predetermined modulation matrix being based on a predetermined plurality of discrete prolate spheroidal (DPS) sequences;
a modulation circuit configured to modulate the precoded vector of data symbols, based on the predetermined modulation matrix, to generate a modulated precoded vector of data symbols; and
a transmitting circuit configured to transmit the modulated precoded vector of data symbols in a Slepian-based waveform to a receiving device.

2. The transmitting device according to claim 1, wherein the predetermined modulation matrix comprises the plurality of DPS sequences in column vectors.

3. The transmitting device according to claim 1, wherein the plurality of DPS sequences is based on a Slepian matrix.

4. The transmitting device according to claim 3, wherein the plurality of DPS sequences comprises one or more eigenvectors of the Slepian matrix.

5. The transmitting device according to claim 1, wherein the predetermined precoding matrix is a matrix that minimises a function ∥F^{M}−SX∥_{F}², for matrices X such that X^{H}. X=1, where F is a discrete Fourier transform matrix, S is the predetermined modulation matrix, and where F^{H} and X^{H} represent the Hermitian of F and the Hermitian of X, respectively.

6. The transmitting device according to claim 1, further comprising storage means storing a plurality of precoding matrices in association with a plurality of modulation matrices, and wherein the precoding circuit is configured to select a precoding matrix associated with the predetermined modulation matrix, and use the selected precoding matrix as the predetermined precoding matrix to generate the precoded vector of data symbols.

7. The transmitting device according to claim 1, wherein the precoding circuit is configured to precode the vector of data symbols generated by the data symbol generation circuit to generate the precoded vector of data symbols by multiplying the vector of data symbols with the predetermined precoding matrix.

8. The transmitting device according to claim 1, wherein the modulation circuit is further configured to modulate the precoded vector of data symbols generated by the precoding circuit to generate the modulated precoded vector of data symbols by multiplying the precoded vector of data symbols with the predetermined modulation matrix.

9. The transmitting device according to claim 1, wherein the data symbol generating circuit is configured to generate the vector of data symbols based on a digital modulation scheme.

10. A receiving device, comprising:
a receiving circuit configured to receive a Slepian-based waveform that comprises a vector of data symbols from a transmitting device;
a demodulation circuit configured to demodulate the vector of data symbols, based on a predetermined demodulation matrix, the predetermined demodulation matrix being based on a predetermined plurality of discrete prolate spheroidal (DPS) sequences, to generate a demodulated vector of data symbols;
a processing circuit configured to apply a predetermined processing matrix to the demodulated vector of data symbols, to generate a processed demodulated vector of data symbols; and
an equalizer circuit configured to execute an equalization on the processed demodulated vector of data symbols to extract a vector of equalized data symbols.

11. The receiving device according to claim 10, wherein the predetermined demodulation matrix comprises the plurality of DPS sequences in row vectors.

12. The receiving device according to claim 10, wherein the plurality of DPS sequences is based on a Slepian matrix.

13. The receiving device according to claim 12, wherein the plurality of DPS sequences comprises one or more eigenvectors of the Slepian matrix.

14. The receiving device according to claim 10, wherein the predetermined demodulation matrix is the Hermitian of a corresponding predetermined modulation matrix, and the predetermined processing matrix is the Hermitian of a matrix that minimises a function ∥F^{M}−SX∥_{F}², for matrices X such that X^{H}. X=1, where F is a discrete Fourier transform matrix, S is the predetermined modulation matrix, and where F^{H} and X^{H} represent the Hermitian of F and the Hermitian of X, respectively.

15. The receiving device according to claim 10, further comprising storage means storing a plurality of processing matrices in association with a plurality of demodulation matrices, and wherein the processing circuit is configured to select a processing matrix associated with the predetermined demodulation matrix, and to use the selected processing matrix as the predetermined processing matrix to generate the processed demodulated vector of data symbols.

16. The receiving device according to claim 10, wherein the processing circuit is configured to process the demodulated vector of data symbol generated by the demodulation circuit to generate the processed demodulated vector of data symbols by multiplying the demodulated vector of data symbols with the predetermined processing matrix.

17. The receiving device according to claim 10, wherein the demodulation circuit is further configured to demodulate the vector of data symbols received by the receiving circuit to generate the demodulated vector of data symbols by multiplying the received vector of data symbols with the predetermined demodulation matrix.

18. The receiving device according to claim 10, further comprising a low-density parity-check, LDPC, decoder configured to decode the vector of equalized data symbols generated by the equalizer circuit.

19. A method comprising:
generating, by a data symbol generation circuit, a vector of data symbols;
precoding, by a precoding circuit, the vector of data symbols, based on a predetermined precoding matrix, to generate a precoded vector of data symbols, the predetermined precoding matrix being based on a predetermined modulation matrix, the predetermined modulation matrix being based on a predetermined plurality of discrete prolate spheroidal (DPS) sequences;
modulating, by a modulation circuit, the precoded vector of data symbols, based on the predetermined modulation matrix, to generate a modulated precoded vector of data symbols; and
transmitting, by a transmitting circuit, the modulated precoded vector of data symbols in a Slepian-based waveform to a receiving device.

20. The method according to claim 19, wherein the predetermined modulation matrix comprises the plurality of DPS sequences in column vectors.
